(19) United States
(12) Patent Application Publication
(10) Pub. No.: US 2026/0129760 A1
(43) Pub. Date: May 7, 2026

(54) ILLUMINATED SERVER-SPECIFIC REGISTERED DUAL INLINE MEMORY MODULE

(71) Applicant: V-COLOR TECHNOLOGY INC., NEW TAIPEI CITY (TW)

(72) Inventor: Tien Shun HO, NEW TAIPEI CITY (TW)

(21) Appl. No.: 19/006,537

(22) Filed: Dec. 31, 2024

(30) Foreign Application Priority Data
Nov. 6, 2024 (TW) 113212102

(51) Int. Cl. H05K 1/18

(52) U.S. Cl. CPC H05K 1/18; H05K 2201/10106; H05K 2201/10159; H05K 2201/10545

(57) ABSTRACT

Provided is an illuminated server-specific R-DIMM, including a printed circuit board, a plurality of dynamic random access memories, a registering clock driver, and at least one light-emitting diode. The dynamic random access memories, the registering clock driver, and the at least one light-emitting diode are all arranged on the printed circuit board. As such, the illuminated server-specific R-DIMM of the present invention can emit light through the light-emitting diode under a stable current, highlighting the aesthetic appearance, which is in line with demands of the chassis design for artificial intelligence creators, game developers, and demonstration workstations or servers.

### CROSS-REFERENCE TO RELATED APPLICATION

This application claims the priority of Taiwanese patent application No. 113212102, filed on Nov. 6, 2024, which is incorporated herewith by reference.

### BACKGROUND OF THE INVENTION

### 1. Field of the Invention

The present invention relates generally to a registered dual inline memory module (R-DIMM), and more particularly, to an illuminated server-specific registered dual inline memory module.

### 2. The Prior Arts

Registered dual inline memory module (R-DIMM) is a memory module specially designed for servers and workstations, mainly used for systems with high stability and reliability requirements. Compared with the unbuffered dual inline memory module (U-DIMM) used in personal computers such as desktop computers and notebook computers, the R-DIMM adds a registering clock driver (RCD), which can help reduce the load on the memory controller and improve system stability.

In order to seize the market share of the e-sports industry, many personal computer manufacturers launched personal computer hosts dedicated to e-sports. In order to attract the attention of players, PC console parts manufacturers also launched luminous parts for PC manufacturers to create more appealing e-sports-specific PC consoles. Players can also purchase luminous parts to assemble their own PC consoles. Parts that light up include memory, hard drives, graphics cards, and central processing units. The memory of personal computer hosts mainly uses U-DIMM because U-DIMM consumes less power and have lower requirements for current stability. Hence, the U-DIMM can have multiple light-emitting diodes to allow the U-DIMM to emit light.

Because the R-DIMM consumes more power and requires a stable current to operate smoothly, the R-DIMM usually does not have a plurality of light-emitting diodes. If the R-DIMM is equipped with light-emitting diodes, the current of the R-DIMM may become unstable when the light-emitting diodes emit light, and the R-DIMM cannot function smoothly.

### SUMMARY OF THE INVENTION

A primary objective of the present invention is to provide an illuminated server-specific R-DIMM, which can emit light under a stable current.

In order to achieve the aforementioned objective, the present invention provides an illuminated server-specific R-DIMM, including a printed circuit board, a plurality of dynamic random access memories (DRAM), and a registering clock driver (RCD), and at least one light-emitting diode, wherein the dynamic random access memories, RCD and the at least one light-emitting diode are all disposed on the printed circuit board.

In a preferred embodiment, the printed circuit board has a first surface and a second surface, and the dynamic random access memories are respectively disposed on the first surface and the second surface, and the RCD is disposed on the first surface, and the at least one light-emitting diode is disposed on the first surface and/or the second surface.

In a preferred embodiment, the illuminated server-specific R-DIMM includes a plurality of light-emitting diodes, and the light-emitting diodes are respectively disposed on the first surface and the second surface.

In a preferred embodiment, the illuminated server-specific R-DIMM includes a plurality of light-emitting diodes, and the light-emitting diodes are respectively disposed on the first surface.

In a preferred embodiment, the illuminated server-specific R-DIMM includes a plurality of light-emitting diodes, and the light-emitting diodes are respectively disposed on the second surface.

The effect of the present invention is that the illuminated server-specific R-DIMM can emit light through the light-emitting diode under a stable current, highlighting and improving esthetics, and is in line with demands of the chassis design for artificial intelligence creators, game developers, and demonstration workstations or servers.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a perspective view of the illuminated server-specific R-DIMM of the present invention.

FIG. 2 is a perspective view of the illuminated server-specific R-DIMM of the present invention from another angle.

FIG. 3 is a front view of the illuminated server-specific R-DIMM of the present invention.

FIG. 4 is a rear view of the illuminated server-specific R-DIMM of the present invention.

FIG. 5 is a perspective view of the illuminated server-specific R-DIMM of the present invention installed on the motherboard and emitting light.

FIG. 6 is a perspective view from another angle of the illuminated server-specific R-DIMM of the present invention installed on the motherboard and emitting light.

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

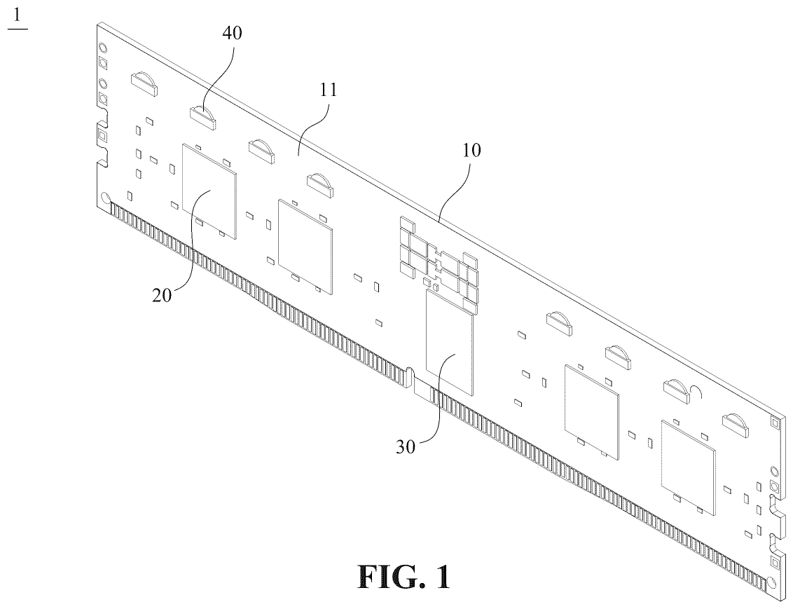

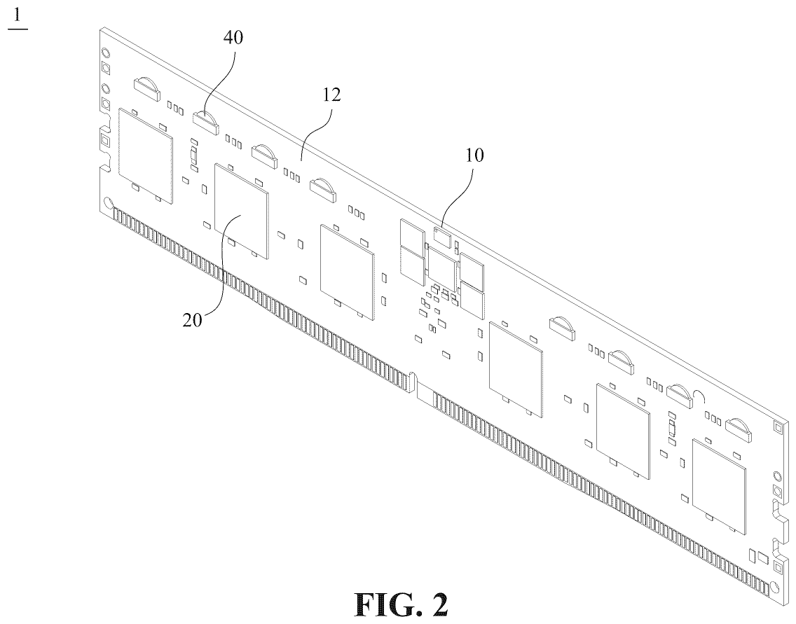

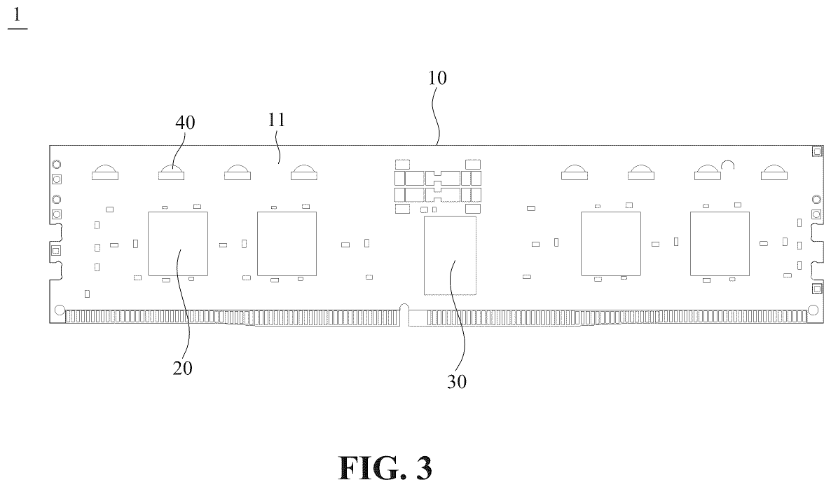

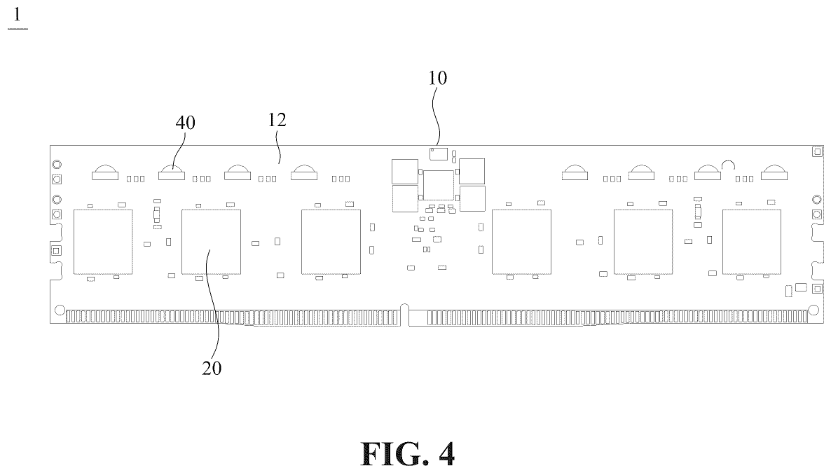

FIG. 1 is a perspective view of the illuminated server-specific R-DIMM of the present invention; FIG. 2 is a perspective view of the illuminated server-specific R-DIMM of the present invention from another angle; FIG. 3 is a front view of the illuminated server-specific R-DIMM of the present invention; and, FIG. 4 is a rear view of the illuminated server-specific R-DIMM of the present invention. As shown in FIGS. 1, 2, 3, and 4, the present invention provides an illuminated server-specific registered dual inline memory module (R-DIMM) 1, including a printed circuit board (PCB) 10, a plurality of dynamic random access memories (DRAM) 20, a registering clock driver (RCD) 30, and at least one light emitting diode (LED) 40. The DRAMs 20, RCD 30, and the LEDs 40 are all arranged on the printed circuit board 10.

The printed circuit board 10 can be made of FR-4 or other high-frequency materials. FR-4 is a common printed circuit board 10 material composed of fiberglass and epoxy resin, has good mechanical strength and electrical properties, and is suitable for most memory applications. For applications requiring high-frequency operation, special high-frequency materials (such as Teflon or ceramics) may be used to reduce signal loss or enhance signal integrity.

The DRAM 20 of illuminated server-specific R-DIMM 1 of the present invention usually uses double data rate synchronous dynamic random access memory (SDRAM), especially versions such as DDR3, DDR4, and DDR5. DDR3 R-DIMM is a common choice in older servers and workstations, providing higher bandwidth and lower power consumption than the previous generation DDR2. DDR4 R-DIMM is the current mainstream server memory standard, providing higher data transfer rates and lower voltages, which can improve system performance and efficiency. Many modern servers and workstations use DDR4 R-DIMMs. As technology advances, DDR5 R-DIMMs begin to enter the market, providing higher bandwidth and capacity and further reducing power consumption. DDR5 R-DIMM is designed to meet the needs of servers and workstations.

The main function of the RCD 30 is to buffer the control signals and data signals from the processor to help reducing the direct load of the processor on the illuminated server-specific R-DIMM 1 of the present invention as well as reducing signal interference and delay. The RCD 30 helps ensuring stable and transmission readiness of signals in multiple modules or high-capacity configurations by providing an additional layer of buffering. The illuminated server-specific R-DIMM 1 of the present invention is designed to support larger memory capacity. The use of the RCD 30 allows the server to connect more DRAMs 20 without affecting system performance. In the illuminated server-specific R-DIMM 1 of the present invention, the RCD 30 is located at the control edge of the printed circuit board 10, and retimes and forwards signals every time the data is accessed, which means that the RCD 30 buffers signals from the processor and transfers these signals to the corresponding DRAM 20 at the appropriate time. The RCD 30 can also assist in coordinating refresh operations of the DRAM 20, ensuring that data remains valid in the capacitors and preventing data loss. Since the RCD 30 reduces the number of direct connections between the processor and the DRAM 20, the load on the system bus is reduced. In high-performance servers and workstations, the use of the RCD 30 improves system stability and reliability, especially in high-load and multi-tasking environments.

In a preferred embodiment, as shown in FIGS. 1, 2, 3, and 4, the printed circuit board 10 has a first surface 11 and a second surface 12. The DRAMs 20 are respectively disposed on the first surface 11 and the second surface 12, the RCD 30 is disposed on the first surface 11, and the at least one light-emitting diode 40 is disposed on the first surface 11 and/or the second surface 12.

In a preferred embodiment, as shown in FIGS. 1, 2, 3 and 4, the illuminated server-specific R-DIMM 1 of the present invention includes a plurality of light-emitting diodes 40. The light-emitting diodes 40 are respectively arranged on the first surface 11 and the second surface 12. In another preferred embodiment, the light-emitting diodes 40 are respectively disposed on the first surface 11. In yet another preferred embodiment, the light-emitting diodes 40 are respectively disposed on the second surface 12. In some other preferred embodiments, there may be only one light-emitting diode 40 and it may be disposed on the first surface 11 or the second surface 12.

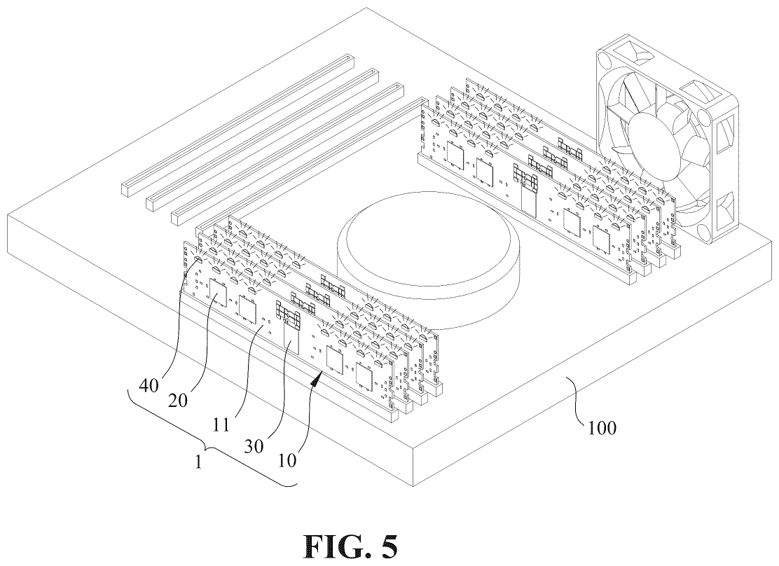

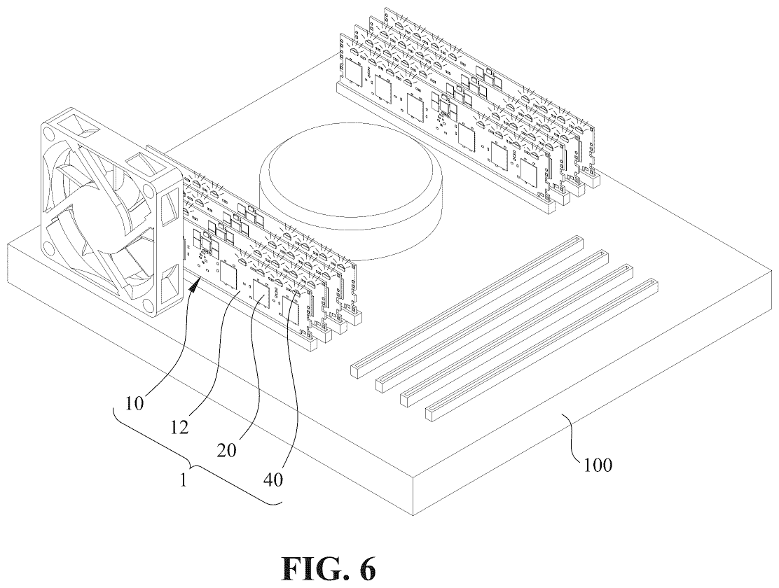

FIG. 5 is a perspective view of the illuminated server-specific R-DIMM 1 of the present invention installed on a motherboard 100 and emitting light. FIG. 6 is a perspective view from another angle of the illuminated server-specific R-DIMM 1 of the present invention installed on the motherboard 100 and emitting light. As shown in FIG. 5 and FIG. 6, a plurality of the illuminated server-specific R-DIMMs 1 of the present invention are installed on a motherboard 100, and the plurality of light-emitting diodes 40 of the plurality of the illuminated server-specific R-DIMMs 1 of the present invention emit light.

As such, the illuminated server-specific R-DIMM 1 of the present invention can emit light through the light-emitting diode 40 under a stable current, highlighting the aesthetic appearance, which is in line with demands of the chassis design for artificial intelligence creators, game developers, and demonstration workstations or servers.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. An illuminated server-specific registered dual inline memory module (R-DIMM), comprising:
printed circuit board;
a plurality of dynamic random access memories (DRAM), disposed on the printed circuit board;
a registering clock driver (RCD), disposed on the printed circuit board; and
at least one light-emitting diode, disposed on the printed circuit board.

2. The illuminated server-specific R-DIMM according to claim 1, wherein the printed circuit board has a first surface and a second surface, and the dynamic random access memories are respectively disposed on the first surface and the second surface, and the RCD is disposed on the first surface, and the at least one light-emitting diode is disposed on the first surface and/or the second surface.

3. The illuminated server-specific R-DIMM according to claim 2, wherein a plurality of light-emitting diodes are included, and the light-emitting diodes are respectively disposed on the first surface and the second surface.

4. The illuminated server-specific R-DIMM according to claim 2, wherein a plurality of light-emitting diodes are included, and the light-emitting diodes are respectively disposed on the first surface.

5. The illuminated server-specific R-DIMM according to claim 2, wherein a plurality of light-emitting diodes are included, and the light-emitting diodes are respectively disposed on the second surface.
